(19) United States
(12) Patent Application Publication
(10) Pub. No.: US 2009/0200580 A1
(43) Pub. Date: Aug. 13, 2009

(54) Image sensor and pixel including a deep photodetector

(75) Inventors: Howard E. Rhodes, San Martin, CA (US); Hidetoshi Nozaki, Santa Clara, CA (US); Sohei Manabe, San Jose, CA (US)

Correspondence Address: BLAKELY SOKOLOFF TAYLOR & ZAFMAN LLP, 1279 Oakmead Parkway, Sunnyvale, CA, 94085-4040, US

(73) Assignee: OMNIVISION TECHNOLOGIES, INC., Sunnyvale, CA (US)

(21) Appl. No.: 12/028,679

(22) Filed: Feb. 8, 2008

(51) Int. Cl. H01L 27/148; H01L 31/18

(52) U.S. Cl. 257/233; 438/75; 257/E27.151; 257/E21.617

(57) ABSTRACT

What is disclosed is an apparatus comprising a transfer gate formed on a substrate and a photodiode formed in the substrate next to the transfer gate. The photodiode comprises a shallow N-type collector formed in the substrate, a deep N-type collector formed in the substrate, wherein a lateral side of the deep N-type collector extends at least under the transfer gate, and a connecting N-type collector formed in the substrate between the deep N-type collector and the shallow N-type collector, wherein the connecting implant connects the deep N-type collector and the shallow N-type collector. Also disclosed is a process comprising forming a deep N-type collector in the substrate, forming a shallow N-type collector formed in the substrate, and forming a connecting N-type collector in the substrate between the deep N-type collector and the shallow N-type collector, wherein the connecting implant connects the deep N-type collector and the shallow N-type collector. A transfer gate is formed on the substrate next to the deep photodiode, wherein a lateral side of the deep N-type collector extends at least under the transfer gate. Other embodiments are disclosed and claimed.

### TECHNICAL FIELD

The present invention relates generally to image sensors and in particular, but not exclusively, to image sensors including pixels having a deep photodetector.

### BACKGROUND

Recent manufacturing improvements in semiconductor processing have markedly reduced the size and enhanced the capabilities of image sensors. As a result of their capabilities and small size, image sensors have become widely used in many applications, including digital still cameras, cellular phones, security cameras, medical, automobile, and other applications. Although miniaturization and integration of image sensors has drastically increased their use, miniaturization has created challenges.

As image sensors have become smaller, the individual components such as pixels that make up an image sensor must also be made correspondingly smaller. As the pixels become smaller, the surface area that can receive incident light is also reduced. The pixel typically has a light-sensing element, such as a photodiode, which receives incident light and produces a signal in relation to the amount of incident light. Thus, as the pixel area (and thus the photodiode area) decreases, the pixel has a lower sensitivity, lower signal saturation level, lower full-well capacity (FWC) and lower quantum efficiency (QE).

One approach to enhance the performance of small pixels is to increase the impurity concentrations of the regions comprising the photodiode. For example, the commonly used pinned photodiode has a structure that is an N-type region surrounded by a P or P-type region. However, increasing the impurity concentration of the N-type region tends to cause undesirable effects, such as an increase of image lag. Other approaches have been tried too, but with limited success.

### BRIEF DESCRIPTION OF THE DRAWINGS

Non-limiting and non-exhaustive embodiments of the present invention are described with reference to the following figures, in which like reference numerals refer to like parts unless otherwise specified.

FIG. 1 is a cross-sectional elevation view of an embodiment of a pixel in an image sensor.

FIG. 2A is a cross-sectional elevation view of an embodiment of a pixel including a deep photodetector.

FIG. 2B is a cross-sectional elevation view of an alternative embodiment of a pixel including a deep photodetector.

FIG. 2C is a cross-sectional elevation view of another alternative embodiment of a pixel including a deep photodetector.

FIG. 2D is a cross-sectional elevation view of yet another alternative embodiment of a pixel including a deep photodetector.

FIG. 3 is a cross-sectional elevation view of an embodiment of a pixel including a deep photodetector with backside illumination.

FIGS. 4A-4F are cross-sectional elevation views of an embodiment of a process for forming a pixel including a deep photodetector.

FIGS. 5A-5F are cross-sectional elevation views of an alternative embodiment of a process for forming a pixel including a deep photodetector.

FIG. 6 illustrates an embodiment of an imaging system using a deep photodetector.

### DETAILED DESCRIPTION OF THE ILLUSTRATED EMBODIMENTS

Embodiments of an apparatus, system and process for an image sensor including pixels with a deep photodetector are described herein. In the following description, numerous specific details are described to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail but are nonetheless encompassed within the scope of the invention.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in this specification do not necessarily all refer to the same embodiment. Furthermore, the particular features, structures, or characteristics may be combined in any suitable manner in one or more embodiments.

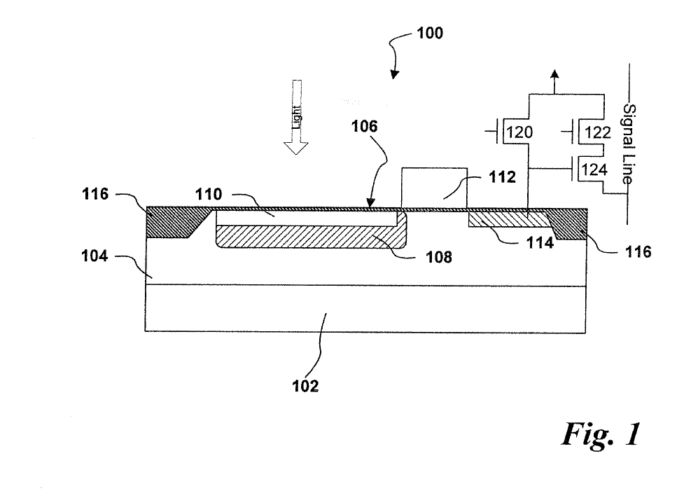

FIG. 1 illustrates an embodiment of a pixel 100, such as those that can be found in a pixel array that forms part of an image sensor. Pixel 100 is an active pixel that uses four transistors; this is known as a 4T active pixel. In other embodiments, however, pixel 100 could include more or less transistors. Pixel 100 is formed in a substrate 104 and includes a photodiode 106, a floating node 114, and transfer gate 112 that transfers charge accumulated in photodiode 106 to floating node 114. Shallow trench isolations (STIs) 116 physically separate and electrically isolate pixel 100 from adjacent pixels in a pixel array.

In pixel 100, photodiode 106 includes a P-type region 110 either at the surface or close to the surface of substrate 104 and a thin and shallow N-type region 108 abutting and at least partially surrounding P-type region 110. In operation, during an integration period (also referred to as an exposure period or accumulation period) photodiode 106 receives incident light, as shown by the arrow in the figure, and generates charge at the interface between P-type region 110 and N-type region 108. After the charge is generated it is held as free electrons in N-type region 108. At the end of the integration period, the electrons held in N-type region 108 (i.e., the signal) are transferred into floating node 114 by applying a voltage pulse to transfer gate 112. When the signal has been transferred to floating node 114, transfer gate 112 is turned off again for the start of another integration period of photodiode 106.

After the signal has been transferred from N-type region 108 to floating node 114, the signal held in floating node 114 is used to modulate amplification transistor 124, which is also known as a source-follower transistor. Finally, address transistor 122 is used to address the pixel and to selectively read out the signal onto the signal line. After readout through the signal line, a reset transistor 120 resets floating node 114 to a reference voltage, which in one embodiment is V_{dd}.

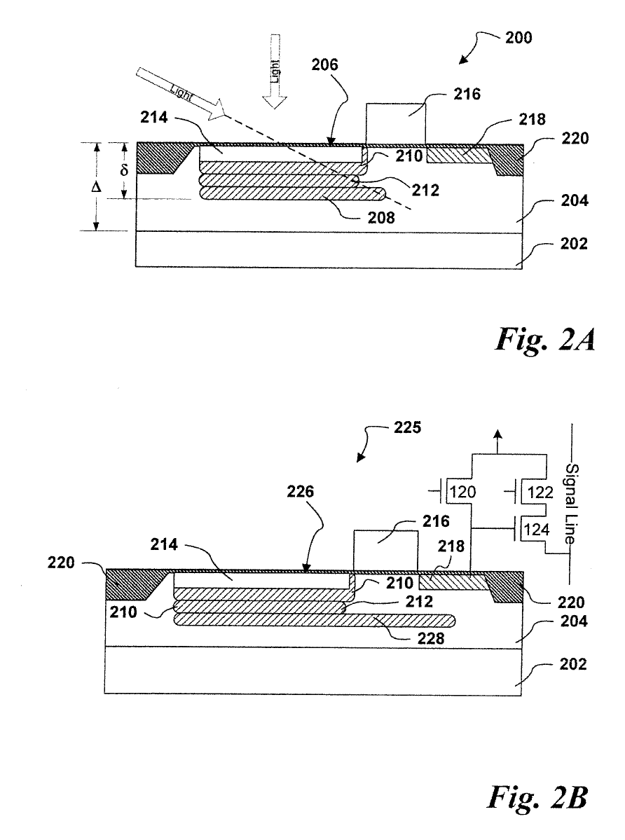

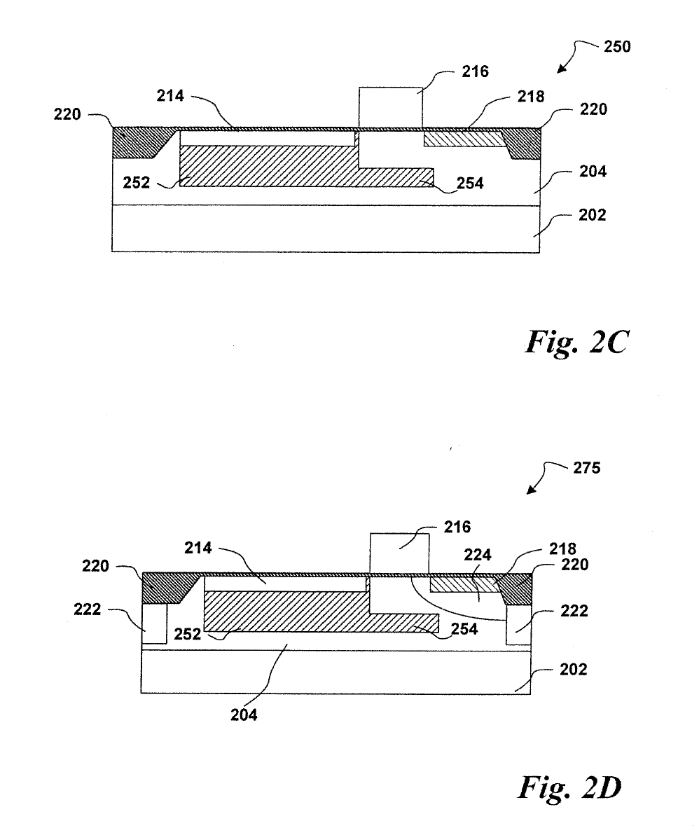

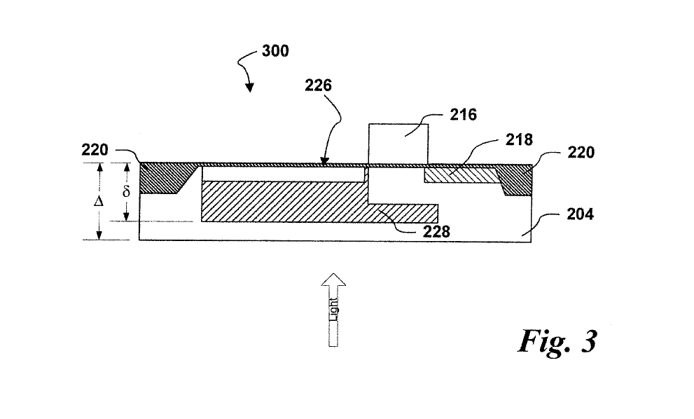

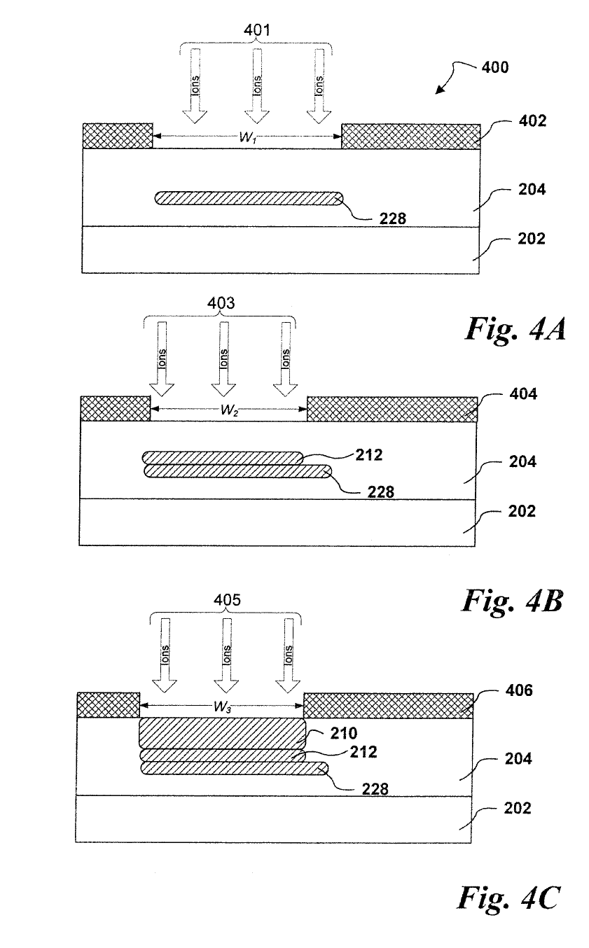

FIG. 2A illustrates an embodiment of a pixel 200. As with pixel 100, in one embodiment pixel 200 can be part of a 4T active pixel similar to pixel 100, but in other embodiments pixel 100 could include a different number of transistors. Pixel 200 is formed in a substrate 204 formed on a base substrate 202, and includes a light-sensitive element 206, a floating node 218 (also referred to as a floating diffusion), and transfer gate 216 that transfers charge accumulated in N-type collectors 208, 210 and 212 to floating node 218. Shallow trench isolations (STIs) 220 physically separate and electrically isolate pixel 200 from adjacent pixels in a pixel array.

Substrate 204 is a doped semiconductor attached to a base substrate 202. In one embodiment, substrate 204 comprises an epitaxial P-type material (also known as “p-epi” material), but in other embodiments substrate 204 can be made up of a non-epitaxial P-type material or some other P-type material. Base substrate 202 can be made up of materials such as polysilicon, single-crystal silicon and the like, and can include therein circuitry and logic that support the functions of pixels in a pixel array as well as other elements that support the function of the image sensor. Alternatively, or in addition, base substrate can be a P-type or N-type semiconductor and/or can include P-type or N-type regions.

Light-sensing element 206 is illustrated as a photodiode, but in other embodiments can include a variety of other devices, including without limitation photogates, photodiodes, pinned photodiodes, partially pinned photodiodes, etc. Photodiode 206 includes a P-type region 214 either at the surface or close to the surface of substrate 204 and an N-type collector region abutting and at least partially surrounding P-type region 214. In one embodiment, P-type region 214 can be a P+ region (i.e., a heavily-doped P-type region), but in other embodiments P-type region 214 can be a P− region (i.e., a lightly-doped P-type region). The N-type collector region includes a deep N-type collector 208 positioned deep within substrate 204, a shallow N-type collector 210 positioned abutting and at least partially surrounding P-type region 214, and a connecting implant 212 that connects deep N-type collector 208 and shallow N-type collector 210. In other embodiments, P-type region 214 can also be replaced by or supplemented by a P-type pinning layer, such as a P+ pinning layer.

Substrate 204 has a thickness A, which in one embodiment can have a value of approximately 4-6 μm but can of course have other values in different embodiments. Deep N-type collector 208 is positioned at a depth δ within the substrate. In one embodiment, values of δ and Δ can be chosen such that the ratio δ/Δ is approximately 0.5, but in other embodiments of pixel 200 the values of δ and Δ can be chosen such that the ratio δ/Δ is between approximately 0.05 and 0.95. In addition to being positioned deep within substrate 204, deep N-type collector 208 is laterally wider than shallow N-type collector 210 and connecting N-type collector 212. In the illustrated embodiment, one lateral edge of deep N-type collector 208 can be substantially aligned with the corresponding lateral edges of shallow N-type collector 210 and connecting N-type collector 212, while the other lateral edge of deep N-type collector 208 is not flush with the lateral edges of the other elements but instead can extend to a position below transfer gate 216.

The conductivities of shallow N-type collector 210, connecting N-type collector 212 and deep N-type collector 208 can of course be tailored to improve or optimize the performance of photodiode 206. In one embodiment, deep N-type collector 208, shallow N-type collector 210 and connecting implant 212 can be N+ regions (i.e., a heavily-doped N-type region), but in other embodiments they can be N− regions (i.e., a lightly-doped N-type region). In still other embodiments, the three collectors can be combinations of N− and N+ regions, meaning that some can be N− regions while others can be N+ regions. In one embodiment, each of the individual collectors 208, 210 and 212 has substantially the same dopant concentration, but in other embodiments the individual collectors 208, 210 and 212 can have different dopant concentrations. In one alternative embodiment, for example, collectors 208, 210 and 212 can have dopant concentrations that are different but of approximately the same order of magnitude. Moreover, in one embodiment individual collectors 208, 210 and 212 can be doped with the same dopant, while in other embodiments different dopants can be used in the individual collectors.

Transfer gate 216 is formed on the surface of substrate 204 between photodiode 206 and a floating node 218, which is also known as a floating diffusion. Transistor 216 is used to transfer the charge accumulated in collectors 208, 210 and 212 (i.e., the signal) to floating node 218, which is used to hold the transferred charge until it can be read out through circuitry such as amplification transistor 124, address transistor 122 and reset transistor 120.

In operation of pixel 200, during an integration period photodiode 206 generates charge at the interface between P-type region 214 and shallow N-type collector 210. Negatively-charged electrons created by photons impinging on the pixel are accumulated during the integration period and held in N-type collectors 208, 210 and 212. Because of the deep N-type collector's large lateral extension, it has a larger area and so provides a far larger target region for light focused on the pixel by micro-lenses or other optics (not shown) that are typically used together with the pixel array of which pixel 200 forms a part. The larger lateral extent of deep N-type collector 208 also allows better collection of charge generated by light incident on the pixel at large angles, as illustrated by the arrows in the figure. Both these qualities results in improved optical quantum efficiency (QE) and sensitivity, especially for longer-wavelength light which penetrate deeper, such as green light and red light. Moreover, the larger collector area provides a larger N-type region to collect and store electrons so that the full well capacity (FWC) of the image sensor is improved.

At the end of the integration period, transfer gate 216 is turned on, creating a channel that transfers the charge then held in N-type collectors 208, 210 and 212 (i.e., the signal) to floating node 218. After the signal has been transferred to floating node 218, transfer gate 216 is turned off again for the start of another integration period of photodiode 206. When the signal has been transferred to floating node 218 it can be read out from the pixel and processed.

FIGS. 2B-2D illustrate various alternative embodiment of a pixel. FIG. 2B illustrates an alternative embodiment of a pixel 225 that shares many similarities with pixel 200. As with pixel 200, pixel 225 is illustrated as a 4T pixel but in other embodiments pixel 225 could include more or less transistors. Pixel 225 is formed in a substrate 204, and includes a light-sensitive element 226, a floating node 218, and a transfer gate 216 that transfers charge accumulated in collectors 228, 212 and 210 to floating node 218. Shallow trench isolations (STIs) 220 physically separate and electrically isolate pixel 225 from adjacent pixels in a pixel array. The primary difference between pixel 225 and pixel 200 is in the deep N-type collector. In pixel 225, deep N-type collector 228 extends laterally much further than deep N-type collector 208 of pixel 200: whereas deep N-collector 208 extends laterally to a position under transfer gate 216, deep N-type collector 228 extends laterally beyond the transfer gate to a position underneath floating node 218, further increasing the area onto which incident light can be focused. The operation of pixel 225 is substantially as described above for pixel 200.

FIG. 2C illustrates an alternative embodiment of a pixel 250 that shares many similarities with pixels 200 and 225. The primary difference between pixel 250 and pixels 200 and 225 is in the structure of the N-type collectors. In pixels 200 and 225, the deep N-type collector, the shallow N-type collector and the connecting implant are all shown as separate implants. In pixel 250, by contrast, the three collectors merge into a single monolithic N-type collector 252, the deepest portion of which has a lateral extension 254 that extends laterally at least as far a position underneath transfer gate 216, although in the illustrated embodiment it extends laterally to a position underneath floating node 218. Despite being monolithic, the doping of N-type collector need not be uniform. The operation of pixel 250 is substantially as described above for pixel 200.

FIG. 2D illustrates an alternative embodiment of a pixel 275 that shares many similarities with pixels 200, 225 and 250. The primary difference between pixel 250 and pixels 200 and 225 is the presence of an array P-well 224 and deep well implants 222. Both array P-well 224 and deep well implants 222, when present, isolate pixel 275 from neighboring pixels in a pixel array by creating a barrier that prevents migration of electrons from one pixel to the other. Although both P-well 224 and deep well implants 222 are shown in the illustrated embodiment, in other embodiments only one of the P-well and the deep well implants need be present. Furthermore, in embodiments where only deep well implants are present there can be two deep well implants as shown, or there can be a greater or lesser number of deep well implants. The operation of pixel 275 is substantially as described above for pixel 200.

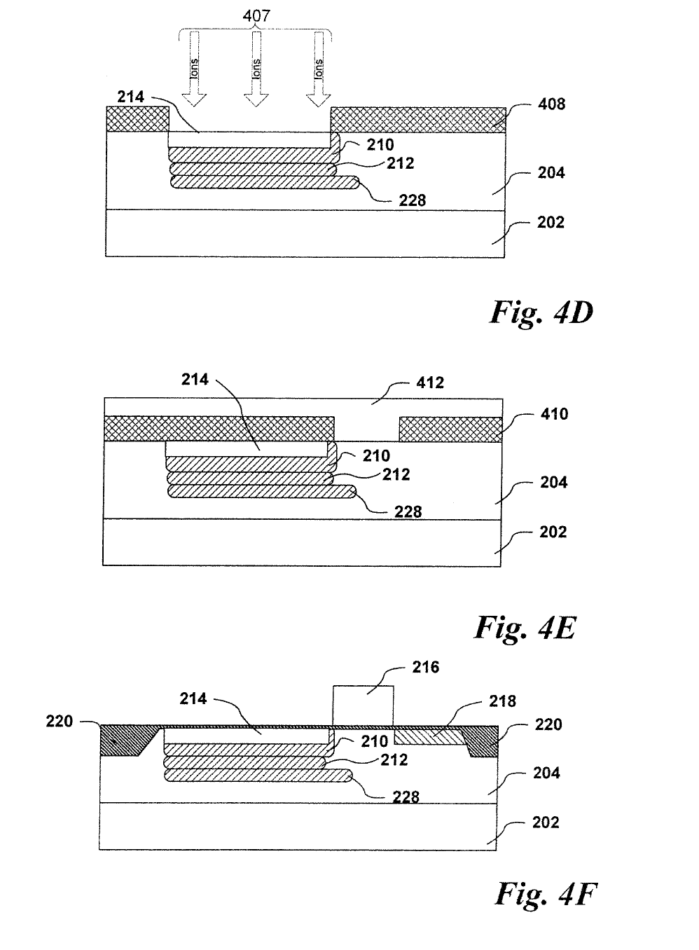

FIG. 3 illustrates an alternative embodiment of a pixel 300. Pixel 300 shares many similarities with pixels 200, 225, 250 and 275; the primary difference between pixel 300 and pixels 200-275 is in the type of illumination for which pixel is designed. Pixels 200-275 are designed primarily for front-side illumination (FSI), meaning that the pixels receive optical energy only from the front side (i.e., the side of substrate 204 on which transfer gate 216 is formed), as shown for example in FIG. 2A. Pixel 300 can similarly use front-side illumination, but can also receive back-side illumination (BSI) as illustrated by the arrow in FIG. 3. During backside illumination, pixel 300 can receive optical energy from the backside instead of, or in addition to, the front side and can use the captured optical energy for image generation.

In pixel 300, substrate 204 has a thickness Δ, and deep N-type collector 208 is positioned at a depth δ within the substrate. In one embodiment pixel 300 will have a substantially thinner substrate than pixels 200-275; the value of [symbol] in pixel 300 can be between 1 [symbol] m and 10 [symbol] m, and the base substrate is entirely removed. The thinner substrate permits better penetration of light incident on the backside of the pixel. In one embodiment, values of δ and Δ can be chosen such that the ratio δ/Δ is approximately 0.5, but in other embodiments of pixel 300 the values of δ and Δ can be chosen such that the ratio δ/Δ is between approximately 0.05 and 0.95.

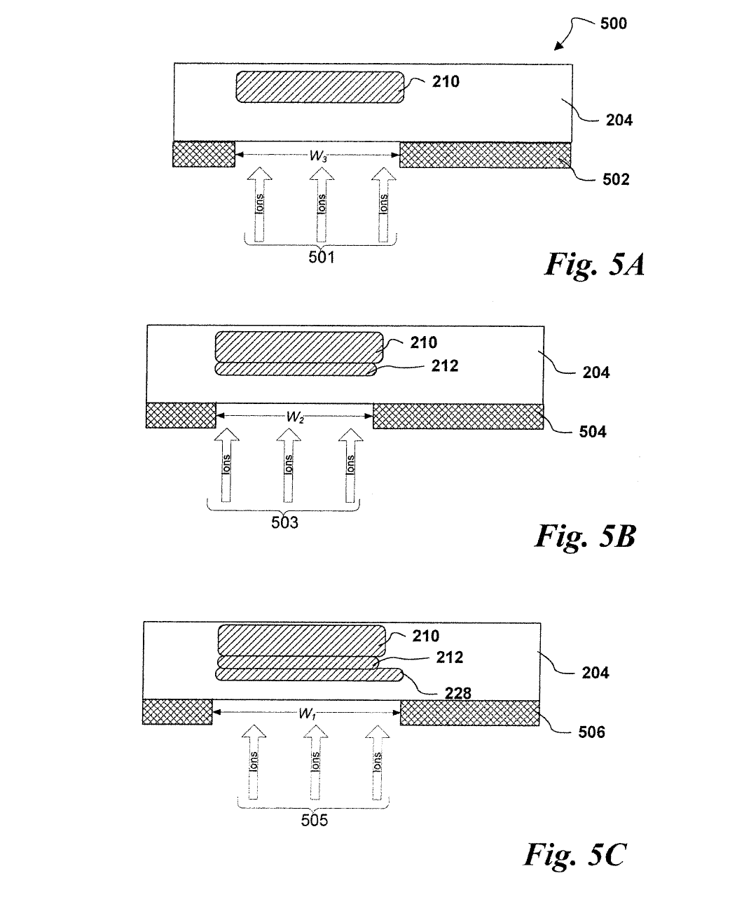

FIGS. 4A-4F illustrate an embodiment of a front-side process 400 for forming pixel 225, although the same process can of course be straightforwardly adapted to make pixels 200, 250 or 275. FIG. 4A illustrates an initial state. After substrates 202 and 204 are prepared for processing, a sacrificial layer 402 is deposited on the front side of substrate 204. Sacrificial layer 402 can be any kind of material that can stop bombarding dopant ions 401 from penetrating into substrate 204 and that can be removed from the substrate without removing any of the substrate or any other features that may be formed on the substrate prior to processing. Examples of sacrificial materials that can be used include certain types of photoresists, silicon oxides, and the like. The thickness of sacrificial layer 402 is also determined by the requirement that no dopant ions 401 should be able to penetrate through to substrate 204.

Once sacrificial layer 402 is deposited on substrate 204, it is patterned and etched to form an opening of width W₁. The value of W₁ can be approximately the same dimension as the intended width of deep N-type collector 228, but can be made smaller or larger to account for inaccuracies in ion implantation and/or post-implantation phenomena such as ion diffusion. After the opening is etched in sacrificial layer 402, the entire assembly is bombarded from above with N-type 401 ions at a specified dosage and energy and for a specified amount of time. The dosage, which in one embodiment can be about 1×10¹² ions/cm² but in other embodiments can of course be different, must be sufficient to give deep N-type collector 228 the required performance characteristics, while the energy of the implanted ions must be sufficient to drive the ions into substrate 204 to the required depth δ (see FIG. 2). After the specified time has passed so that the size and ion concentration of deep N-type collector are as required, the ion bombardment stops.

FIG. 4B illustrates the next part of process 400. Starting with the assembly as shown in FIG. 4A, sacrificial layer 402 is stripped off the top of substrate 204 and a new sacrificial layer 404 is deposited on the top surface of substrate 204. Sacrificial layer 404 can, in one embodiment, have substantially the same thickness and composition as sacrificial layer 402, but in other embodiments can have a different thickness and/or composition. After it is deposited, sacrificial layer 404 is patterned and etched to create an opening with width W₂. The value of W₂ will be approximately the same dimension as the intended width of connecting N-type collector 212, but can be made smaller or larger to account for inaccuracies in implantation and/or post-implantation phenomena such as ion diffusion. After the opening is etched in sacrificial layer 404, the entire assembly is bombarded from above with N-type ions 403 at a specified dosage and energy and for a specified amount of time to produce position connecting N-type collector at the desired depth in substrate 204 and to give it the required performance characteristics. After the specified time has passed so that the size and ion concentration of connecting N-type collector are as required, the ion bombardment stops.

FIG. 4C illustrates the next part of process 400. Starting with the assembly as shown in FIG. 4B, sacrificial layer 404 is stripped off the top of substrate 204 and a new sacrificial layer 406 is deposited on the top surface of substrate 204. Sacrificial layer 406 can, in one embodiment, have substantially the same thickness and composition as sacrificial layers 402 or 404, but in other embodiments can have a different thickness and/or composition. After it is deposited, sacrificial layer 406 is patterned and etched to create an opening with width W₃. The value of W₃ can be approximately the same dimension as the intended width of shallow N-type collector 210, but can be made smaller or larger to account for inaccuracies in implantation and/or post-implantation phenomena such as ion diffusion. In situations where shallow N-type collector 210 and connecting N-type collector 212 are of roughly equal width, sacrificial layer 404 need not be replaced by sacrificial material 406 but can instead be re-used to form shallow N-type collector 210, since it will already have an opening of approximately the right dimension.

After the opening is etched in sacrificial layer 406, the entire assembly is bombarded from above with N-type ions 405 at a specified dosage and energy and for a specified amount of time to position shallow N-type collector 212 at the desired depth in substrate 204 and to give it the required performance characteristics. After the specified time has passed so that the size and ion concentration of connecting N-type collector 212 are as required, the ion bombardment stops.

FIG. 4D illustrates the next part of process 400. Starting with the assembly as shown in FIG. 4C, sacrificial layer 406 is stripped off the top of substrate 204 and a new sacrificial layer 408 is deposited on the top surface of substrate 204. Sacrificial layer 408 can, in one embodiment, have substantially the same thickness and composition as sacrificial layers 402-406, but in other embodiments can have a different thickness and/or composition. After it is deposited, sacrificial layer 408 is patterned and etched to create an opening with a width that corresponds to the desired width of P-type region 214. The opening's width can be approximately the same dimension as the intended width of P-type region 214, but can be made smaller or larger to account for inaccuracies in implantation and/or post-implantation phenomena such as ion diffusion.

After the opening is etched into sacrificial layer 408, the entire assembly is bombarded from above with P-type ions 407 at a specified dosage and energy and for a specified amount of time to position P-type region 214 at the desired depth in substrate 204 and to give it the required performance characteristics. After the specified time has passed so that the size and ion concentration of P-type region 214 are as required, the ion bombardment stops.

FIG. 4E illustrates the next part of process 400. Starting with the assembly as shown in FIG. 4D, sacrificial layer 408 is stripped off the top of substrate 204 and a new sacrificial layer 410 is deposited on the top surface of substrate 204. Sacrificial layer 410 can, in one embodiment, have substantially the same thickness and composition as sacrificial layers 402-408, but since it need not resist ion bombardment it can have a different thickness and/or composition. After it is deposited, sacrificial layer 410 is patterned and etched to create an opening with a width that corresponds to the desired width of transfer gate 216. After the opening is etched into sacrificial layer 410, a layer 412 of a conductor or semiconductor is deposited onto sacrificial layer 410 and into the opening etched in the sacrificial layer. After layer 412 is deposited it can be planarized, for example using chemical-mechanical polishing (CMP) to remove the excess conductor or semiconductor from the field surrounding the opening. After planarization sacrificial layer 412 is removed, leaving transfer gate 216 in place.

FIG. 4F illustrates the end result of process 400. Starting with the assembly as shown in FIG. 4E, floating node 218, which in one embodiment can be a lightly doped (i.e., an N−) implant, and the shallow-trench isolations (STIs) 220 can be formed by appropriately patterning, implanting and etching substrate 204 and/or sacrificial layers deposited on substrate 204.

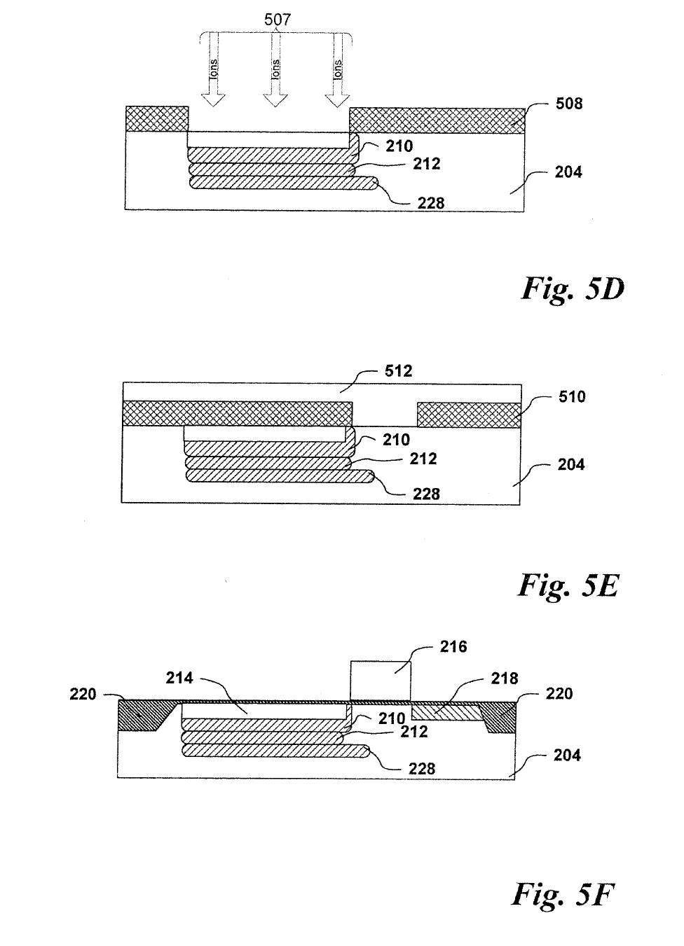

FIGS. 5A-5F illustrate an embodiment of a back-side process 500 for forming pixel 225, although the same process can of course be straightforwardly adapted to make pixels 200, 250 or 275. FIG. 5A illustrates an initial state. After substrate 204 is prepared for processing, a sacrificial layer 502 is first deposited on the back side of substrate 204. Sacrificial layer 502 can be any kind of material that can stop bombarding dopant ions 501 from penetrating to the substrate and that can be removed from the substrate without removing any of the substrate or any other features that may be formed on the substrate prior to processing. Examples of sacrificial materials that can be used include certain types of photoresists, silicon oxides, and the like. The thickness of sacrificial layer 502 is also determined by the requirement that no dopant ions should be able to penetrate through it to the underlying substrate.

Once sacrificial layer 502 is deposited on substrate 204, it is patterned and etched to form an opening of width W₃. The value of W₃ can be approximately the same dimension as the intended width of shallow N-type collector 210, but can be made smaller or larger to account for inaccuracies in implantation and/or post-implantation phenomena such as ion diffusion. After the opening is etched in sacrificial layer 502, the entire backside of the assembly is bombarded with N-type ions 501 at a specified dosage and energy and for a specified amount of time. The dosage, which in one embodiment can be about 1×10¹² ions/cm² but in other embodiments can of course be different, must be sufficient to give shallow N-type collector 210 the required performance characteristics, while the energy of the implanted ions must be sufficient to drive the ions into substrate 204 to the required depth δ. After the specified time has passed so that the size and ion concentration of shallow N-type collector 210 are as required, the ion bombardment stops.

FIG. 5B illustrates the next part of process 500. Starting with the assembly as shown in FIG. 5A, sacrificial layer 502 is stripped off the backside of substrate 204 and a new sacrificial layer 504 is deposited on the backside. Sacrificial layer 504 can, in one embodiment, have substantially the same thickness and composition as sacrificial layer 502, but in other embodiments can have a different thickness and/or composition. After it is deposited, sacrificial layer 504 is patterned and etched to create an opening with width W₂. The value of W₂ will be approximately the same dimension as the intended width of connecting N-type collector 212, but can be made smaller or larger to account for inaccuracies in implantation and/or post-implantation phenomena such as ion diffusion. In situations where shallow N-type collector 210 and connecting N-type collector 212 are of roughly equal width, sacrificial layer 502 need not be replaced by sacrificial material 504 but can instead be re-used to form connecting N-type collector 212 since it will already have an opening of approximately the right dimension in it.

After the opening is etched in sacrificial layer 504, the entire backside of the assembly is bombarded with N-type ions 503 at a specified dosage and energy and for a specified amount of time to give position connecting N-type collector at the desired depth in substrate 204 and to give it the required performance characteristics. After the specified time has passed so that the size and ion concentration of connecting N-type collector 212 are as required, the ion bombardment stops.

FIG. 5C illustrates the next part of process 500. Starting with the assembly as shown in FIG. 5B, sacrificial layer 504 is stripped off the backside of substrate 204 and a new sacrificial layer 506 is deposited on the backside. Sacrificial layer 506 can, in one embodiment, have substantially the same thickness and composition as sacrificial layers 502 or 504, but in other embodiments can have a different thickness and/or composition. After it is deposited, sacrificial layer 506 is patterned and etched to create an opening with width W₁. The value of W₁ can be approximately the same dimension as the intended width of deep N-type collector 228, but can be made smaller or larger to account for inaccuracies in implantation and/or post-implantation phenomena such as ion diffusion.

After the opening is etched in sacrificial layer 506, the backside of the entire assembly is bombarded with N-type ions 505 at a specified dosage and energy and for a specified amount of time to position deep N-type collector 228 at the desired depth in substrate 204 and to give it the required performance characteristics. After the specified time has passed so that the size and ion concentration of deep N-type collector 228 are as required, the ion bombardment stops.

FIG. 5D illustrates the next part of process 500. Starting with the assembly as shown in FIG. 5C, sacrificial layer 508 is deposited on the top surface of substrate 204. Sacrificial layer 508 can, in one embodiment, have substantially the same thickness and composition as sacrificial layers 502-506, but in other embodiments can have a different thickness and/or composition. After it is deposited, sacrificial layer 508 is patterned and etched to create an opening with a width that corresponds to the desired width of P-type region 214. The opening's width can be approximately the same dimension as the intended width of P-type region 214, but can be made smaller or larger to account for inaccuracies in implantation and/or post-implantation phenomena such as ion diffusion. After the opening is etched into sacrificial layer 508, the entire assembly is bombarded from above with P-type ions 507 at a specified dosage and energy and for a specified amount of time to position P-type region 214 at the desired depth in substrate 204 and to give it the required performance characteristics. After the specified time has passed so that the size and ion concentration of P-type region 214 are as required, the ion bombardment stops.

FIG. 5E illustrates the next part of process 500. Starting with the assembly as shown in FIG. 5D, sacrificial layer 508 is stripped off the front of substrate 204 and a new sacrificial layer 510 is deposited on the top surface of substrate 204. Sacrificial layer 510 can, in one embodiment, have substantially the same thickness and composition as sacrificial layers 502-508, but since it need not resist ion bombardment it can have a different thickness and/or composition. After it is deposited, sacrificial layer 510 is patterned and etched to create an opening with a width that corresponds to the desired width of transfer gate 216 and a layer 512 of a conductor or semiconductor is deposited onto sacrificial layer 510 and into the opening etched in the sacrificial layer. After layer 512 is deposited it can be planarized, for example using chemical-mechanical polishing (CMP), to remove the excess conductor or semiconductor from the field surrounding the opening. After planarization sacrificial layer 512 is removed, leaving transfer gate 216 in place.

FIG. 5F illustrates the end result of process 500. Starting with the assembly as shown in FIG. 4E, floating node 218, which in one embodiment can be a lightly doped (i.e., an N−) implant, and the shallow-trench isolations (STIs) 220 can be formed by appropriately patterning, implanting and etching substrate 204 and/or sacrificial layers deposited on substrate 204. Although in the illustrated embodiment of process 500 no features are present on the front side of substrate 204 during formation of the various N-type and P-type regions, in other embodiments front-side features such as transfer gate 216, floating node 218, STIs 220 and P-type region 214 can be formed before any backside implantation or at some intermediate stage of backside implantation.

Although FIGS. 4A-4F illustrate a front-side process for forming a pixel and FIGS. 5A-5F illustrate a backside process for forming a pixel, in other embodiments a pixel can be formed using a combination of these two processes; for example, in one embodiment some of the ion implantation can be done with a front-side process while some is done with a backside process.

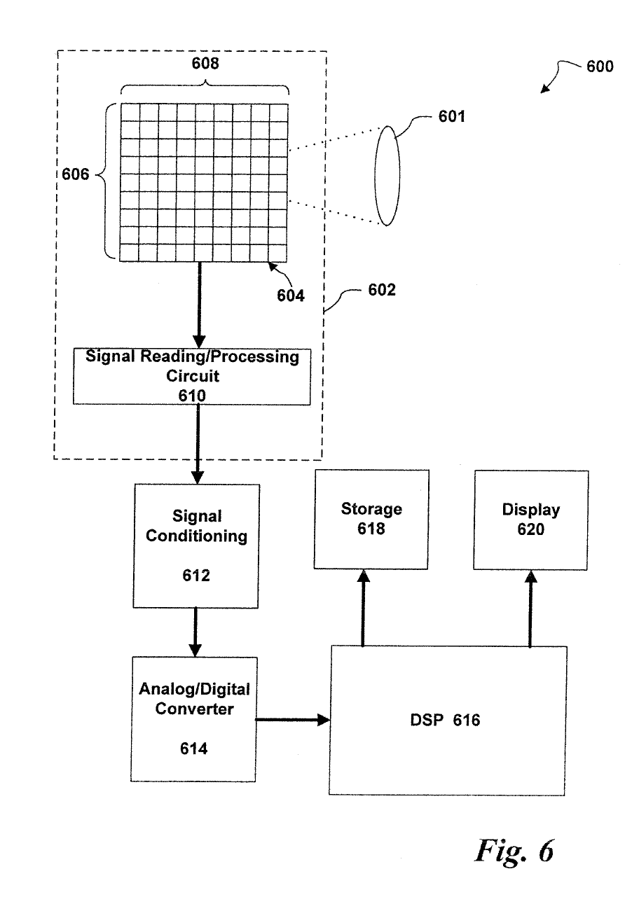

FIG. 6 illustrates an embodiment of an imaging system 600 that can employ one or more of pixels 200, 225, 250, 275 and 300. Optics 601, which can include refractive, diffractive or reflective optics or combinations of these, are coupled to image sensor 602 to focus an image onto the pixels in pixel array 604. Pixel array 604 captures the image and the remainder of apparatus 600 processes the pixel data from the image

Image sensor 602 comprises a pixel array 604 and a signal reading and processing circuit 610. Pixel array 604 is two-dimensional and includes a plurality of pixels including one or more of pixels 200, 225, 250, 275 and 300, or alternative embodiments thereof, arranged in rows 606 and columns 608. During operation of pixel array 604 to capture an image, each pixel in the array captures incident light (i.e., photons) during a certain exposure period and converts the collected photons into an electrical charge. The electrical charge generated by each pixel can be read out as an analog signal, and a characteristic of the analog signal such as its charge, voltage or current will be representative of the intensity of light that was incident on the pixel during the exposure period.

The illustrated pixel array 604 is regularly shaped, but in other embodiments the array can have a regular or irregular arrangement different than shown and can include more or less pixels, rows and columns than shown. Moreover, in different embodiments pixel array 604 can be a color image sensor including red, green and blue pixels designed to capture images in the visible portion of the spectrum, or can be a black-and-white image sensor and/or an image sensor designed to capture images in the invisible portion of the spectrum, such as infra-red or ultraviolet.

Image sensor 602 includes signal reading and processing circuit 610. Among other things, circuit 610 can include circuitry and logic that methodically read analog signals from each pixel and filter these signals, correct for defective pixels, and so forth. Although shown in the drawing as an element separate from pixel array 604, in some embodiments reading and processing circuit 610 can be integrated with pixel array 604 on the same substrate or can comprise circuitry and logic embedded within the pixel array. In other embodiments, however, reading and processing circuit 610 can be an element external to pixel array 104 as shown in the drawing. In still other embodiments, reading and processing circuit 610 can be a element not only external to pixel array 604, but also external to image sensor 602.

Signal conditioner 612 is coupled to image sensor 602 to receive and condition analog signals from pixel array 604 and reading and processing circuit 610. In different embodiments, signal conditioner 612 can include various components for conditioning analog signals. Examples of components that can be found in signal conditioner include filters, amplifiers, offset circuits, automatic gain control, etc. Analog-to-digital converter (ADC) 614 is coupled to signal conditioner 612 to receive conditioned analog signals corresponding to each pixel in pixel array 604 from signal conditioner 612 and convert these analog signals into digital values.

Digital signal processor (DSP) 616 is coupled to analog-to-digital converter 614 to receive digitized pixel data from ADC 614 and process the digital data to produce a final digital image. DSP 616 can include a processor and an internal memory in which it can store and retrieve data. After the image is processed by DSP 616, it can be output to one or both of a storage unit 618 such as a flash memory or an optical or magnetic storage unit and a display unit such as an LCD screen.

The above description of illustrated embodiments of the invention, including what is described in the abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. These modifications can be made to the invention in light of the above detailed description.

The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

1. An apparatus comprising:
a transfer gate formed on a substrate;
a photodiode formed in the substrate next to the transfer gate, the photodiode comprising:
a shallow N-type collector formed in the substrate,
a deep N-type collector formed in the substrate, wherein a lateral side of the deep N-type collector extends at least under the transfer gate, and
a connecting N-type collector formed in the substrate between the deep N-type collector and the shallow N-type collector, wherein the connecting implant connects the deep N-type collector and the shallow N-type collector.

2. The apparatus of claim 1 wherein the deep N-type collector, the shallow N-type collector and the N-type connecting implant have different dopant concentrations.

3. The apparatus of claim 1, further comprising a floating node formed in the substrate on the opposite side of the transfer gate from the photodiode.

4. The apparatus of claim 4 wherein the lateral side of the deep N-type collector extends underneath the floating node.

5. The apparatus of claim 1 wherein the shallow N-type collector, the deep N-type collector and the N-type connecting implant have different dopant concentrations.

6. The apparatus of claim 5 wherein the dopant concentrations of the deep N-type collector, the shallow N-type collector and the N-type connecting implant have concentrations of the same order of magnitude.

7. The apparatus of claim 1, further comprising a P+ pinning layer between the substrate surface and the shallow N-type collector.

8. The apparatus of claim 1 wherein the substrate is a P-type epitaxial substrate.

9. The apparatus of claim 1 wherein the deep N-type collector is located between 10 percent and 90 percent of the thickness of the substrate.

10. A system comprising:
a pixel array comprising a plurality of pixels, wherein at least one of the pixel in the array comprises:
a transfer gate formed on a substrate;
a photodiode formed in the substrate next to the transfer gate, the photodiode comprising:
a shallow N-type collector formed in the substrate,
a deep N-type collector formed in the substrate, wherein a lateral side of the deep N-type collector extends at least under the transfer gate, and
a connecting N-type collector formed in the substrate between the deep N-type collector and the shallow N-type collector, wherein the connecting implant connects the deep N-type collector and the shallow N-type collector; and
a signal reading and processing circuit coupled to the pixel array.

11. The system of claim 10 wherein the deep N-type collector, the shallow N-type collector and the N-type connecting implant have different dopant concentrations.

12. The system of claim 10, wherein the at least one pixel further comprises a floating node formed in the substrate on the opposite side of the transfer gate from the photodiode.

13. The system of claim 10 wherein the lateral side of the deep N-type collector extends underneath the floating node.

14. The system of claim 10 wherein the shallow N-type collector, the deep N-type collector and the N-type connecting implant have different dopant concentrations.

15. The system of claim 14 wherein the dopant concentrations of the deep N-type collector, the shallow N-type collector and the N-type connecting implant have concentrations of the same order of magnitude.

16. The system of claim 10, further comprising a p+ pinning layer between the substrate surface and the shallow N-type collector.

17. The system of claim 10 wherein the substrate is a p-type epitaxial substrate.

18. The system of claim 10 wherein the deep N-type collector is located between 10 percent and 90 percent of the thickness of the substrate.

19. A process comprising:
forming a deep photodiode in a substrate, wherein forming a photodiode comprises:
forming a deep N-type collector in the substrate, and
forming a shallow N-type collector formed in the substrate,
forming a connecting N-type collector in the substrate between the deep N-type collector and the shallow N-type collector,
wherein the connecting implant connects the deep N-type collector and the shallow N-type collector.
forming a transfer gate on the substrate next to the deep photodiode,
wherein a lateral side of the deep N-type collector extends at least under the transfer gate.

20. The process of claim 19, further comprising forming a floating node on the opposite side of the transfer gate from the photodiode.

21. The process of claim 20 wherein the lateral side of the deep N-type collector extends underneath the floating node.

22. The process of claim 19 wherein the shallow N-type collector, the deep N-type collector and the N-type connecting implant have different dopant concentrations.

23. The process of claim 22 wherein the dopant concentrations of the deep N-type collector, the shallow N-type collector and the N-type connecting implant have concentrations of the same order of magnitude.

24. The process of claim 19 further comprising forming a p+ pinning layer between the substrate surface and the shallow N-type collector.

25. The process of claim 19 wherein the deep N-type collector is located between 10 percent and 90 percent of the thickness of the substrate.

26. The process of claim 19 wherein the deep N-type collector, the shallow N-type collector and the N-type connecting implant are all formed using front-side implantation.

27. The process of claim 19 wherein the deep N-type collector, the shallow N-type collector and the N-type connecting implant are all formed using back-side implantation.

28. The process of claim 19 wherein one or more of the deep N-type collector, the shallow N-type collector and the N-type connecting implant are formed using front-side implantation and the remainder are formed using back-side implantation.
